(19) United States
(12) Patent Application Publication
(10) Pub. No.: US 2024/0387235 A1
(43) Pub. Date: Nov. 21, 2024

(54) SUBSTRATE PROCESSING APPARATUS

(71) Applicant: Tokyo Electron Limited, Tokyo (JP)

(72) Inventors: Ryosuke Moriyama, Koshi City (JP); Yukihiro Mimaki, Koshi City (JP)

(21) Appl. No.: 18/663,644

(22) Filed: May 14, 2024

(30) Foreign Application Priority Data
May 16, 2023 (JP) 2023-081032

(51) Int. Cl. H01L 21/687; H01L 21/67

(52) U.S. Cl. CPC H01L 21/68764; H01L 21/67017; H01L 21/68742

(57) ABSTRACT

A substrate processing apparatus includes a substrate holder having a plate positioned below a substrate; and substrate gripping members provided on a periphery of the plate, the plate having notches at the periphery thereof; a rotational driver; lift pins configured to support a periphery of the substrate from below and configured to be moved up and down; sliding members provided on the plate to be slid in a horizontal direction, each of the sliding members being configured to be moved between a closing position where the notch is closed and an opening position where the notch is opened to allow the lift pin to be moved up and down through the notch; and operating members configured to be moved up and down, each of the operating members being configured to slide the sliding member by being moved up and down while being engaged with the sliding member.

### CROSS-REFERENCE TO RELATED APPLICATION

This application claims the benefit of Japanese Patent Application No. 2023-081032 filed on May 16, 2023, the entire disclosure of which is incorporated herein by reference.

### TECHNICAL FIELD

The various aspects and embodiments described herein pertain generally to a substrate processing apparatus.

### BACKGROUND

In a manufacturing process for a semiconductor device, with a rear surface (a surface on which no device is to be formed) of a substrate such as a semiconductor wafer facing upwards, a brush processing is performed to polish or clean the rear surface by using a brush. An example of a processing device that performs such a brush processing is described in Patent Document 1.

The processing device of Patent Document 1 includes a spin chuck configured to hold the substrate horizontally and rotate it around a vertical axis. In order to suppress a liquid supplied to the rear surface of the substrate during the processing from reaching a front surface (a surface on which a device is to be formed) of the substrate, the spin chuck has a disk-shaped member (plate) slightly larger than the substrate and located below the substrate, and a nitrogen gas is supplied into a gap between the substrate and the disk-shaped member. When the substrate is transferred between an arm of a substrate transfer mechanism and the spin chuck, three lift pins (substrate elevating member) lift up the substrate while supporting a periphery of the substrate from below. In order to allow the lift pins to rise, the disk-shaped member has notches formed at a periphery thereof.
Patent Document 1: Japanese Patent Laid-open Publication No. 2017-183310

### SUMMARY

In an exemplary embodiment, a substrate processing apparatus includes a substrate holder, configured to hold a substrate horizontally, including a plate positioned below the substrate when the substrate holder is holding the substrate; and multiple substrate gripping members provided on a periphery of the plate and configured to hold the substrate, the plate having multiple notches at the periphery thereof; a rotational driver configured to rotate the substrate holder around a vertical axis; multiple lift pins configured to support a periphery of the substrate from below, and configured to be moved up and down through the notches of the plate; multiple sliding members provided on the plate of the substrate holder and configured to be slid in a horizontal direction, each of the multiple sliding members being configured to be moved between a closing position where the corresponding notch of the plate is at least partially closed and an opening position where the corresponding notch of the plate is opened to allow the corresponding lift pin to be moved up and down through the corresponding notch; and multiple operating members provided below the plate of the substrate holder to be moved up and down and allowed to be respectively engaged with the sliding members, each of the multiple operating members being configured to slide the corresponding sliding member in the horizontal direction by being moved up and down while being engaged with the corresponding sliding member.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic transversal cross sectional view of a substrate processing system according to an exemplary embodiment of a substrate processing apparatus;

FIG. 2 is a schematic longitudinal cross sectional view illustrating an example configuration of a processing device belonging to the substrate processing system of FIG. 1;

FIG. 3 is a schematic perspective view illustrating an example structure of a part of a periphery of a plate of a spin chuck belonging to the processing device of FIG. 2;

FIG. 4 is a schematic cross sectional view taken along line IV-IV of FIG. 2, schematically illustrating an example configuration of a guide member for a slider provided at the plate shown in FIG. 3;

FIG. 5A is a schematic diagram illustrating an effect of an inclined surface of the periphery of the plate of the spin chuck and an inclined surface of the slider shown in FIG. 3;

FIG. 5B is a schematic diagram illustrating the effect of the inclined surface of the periphery of the plate of the spin chuck and the inclined surface of the slider shown in FIG. 3; and

FIG. 5C is a schematic diagram illustrating the effect of the inclined surface of the periphery of the plate of the spin chuck and the inclined surface of the slider shown in FIG. 3.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, an exemplary embodiment of the present disclosure will be described with reference to the accompanying drawings.

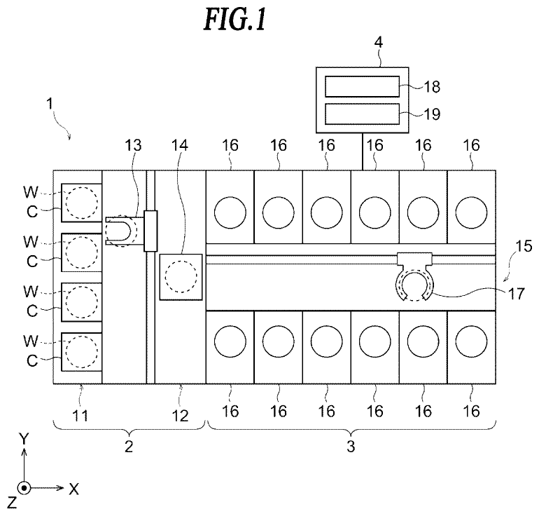

A schematic configuration of a substrate processing system 1 (an example of a liquid processing apparatus) according to the exemplary embodiment will be explained with reference to FIG. 1. FIG. 1 is a diagram illustrating the schematic configuration of the substrate processing system 1 according to the exemplary embodiment. In the following, in order to clarify positional relationships, the X-axis, the Y-axis and the Z-axis which are orthogonal to each other will be defined. The positive Z-axis direction will be regarded as a vertically upward direction.

As shown in FIG. 1, the substrate processing system 1 includes a carry-in/out station 2 and a processing station 3. The carry-in/out station 2 and the processing station 3 are provided adjacent to each other.

The carry-in/out station 2 is equipped with a carrier placing section 11 and a transfer section 12. In the carrier placing section 11, a plurality of carriers C is placed to horizontally accommodate therein a plurality of substrates, i.e., semiconductor wafers W (hereinafter, simply referred to as “wafers W”) in the present exemplary embodiment.

The transfer section 12 is provided adjacent to the carrier placing section 11 and equipped with a substrate transfer device 13 and a transit module 14. The substrate transfer device 13 is equipped with a wafer holding mechanism configured to hold the wafer W. Further, the substrate transfer device 13 is movable in a horizontal direction and a vertical direction and pivotable around a vertical axis, and serves to transfer the wafer W between the carrier C and the transit module 14 by using the wafer holding mechanism.

The processing station 3 is provided adjacent to the transfer section 12. The processing station 3 is equipped with a transfer section 15 and a plurality of processing devices 16. The plurality of processing devices 16 are arranged on both sides of the transfer section 15.

The transfer section 15 has a substrate transfer device 17 therein. The substrate transfer device 17 is equipped with a wafer holding mechanism configured to hold the wafer W. Further, the substrate transfer device 17 is configured to be movable in a horizontal direction and a vertical direction and pivotable around a vertical axis. The substrate transfer device 17 serves to transfer the wafer W between the transit module 14 and the processing device 16 by using the wafer holding mechanism.

The processing device 16 is configured to perform a substrate processing on the wafer W transferred by the substrate transfer device 17. The processing device 16 performs such a processing as a brush processing, a cleaning processing, or the like on the wafer W.

The substrate processing system 1 is equipped with a control device 4. The control device 4 is, for example, a computer, and includes a control operation module 18 and a storage 19. The storage 19 stores therein a program for controlling various processings performed in the substrate processing system 1. The control operation module 18 controls an operation of the substrate processing system 1 by reading and executing the program stored in the storage 19.

Further, the program may have been recorded in a computer-readable recording medium and may be installed from the recording medium to the storage 19 of the control device 4. The computer-readable recording medium may be, by way of example, a hard disk (HD), a flexible disk (FD), a compact disk (CD), a magnet optical disc (MO), a memory card, or the like.

In the substrate processing apparatus 1 configured as described above, the substrate transfer device 13 of the carry-in/out station 2 first takes out the wafer W from the carrier C placed in the carrier placing section 11, and places the taken substrate W in the transit module 14. The wafer W placed in the transit module 14 is taken out from the transit module 14 by the substrate transfer device 17 of the processing station 3 and carried into the processing device 16.

The wafer W introduced into the processing device 16 is subjected to a substrate processing by the processing device 16, and is then carried out from the processing device 16 by the substrate transfer device 17 and placed in the transit module 14. The processed wafer W placed in the transfer module 14 is returned back into the carrier C of the carrier placing section 11 by the substrate transfer device 13.

If the processing device 16 is a brush processing device configured to brush a rear surface of the wafer W, a reverser (not shown) is provided to turn the wafer W over. In this case, the reverser may be provided in place of the processing device 16 at some of the locations where the processing devices 16 are provided in FIG. 1. Alternatively, the reverser may be provided above or below the transit module 14. In this case, a transfer device configured to transfer the wafer W between the reverser and the transit module 14 may be provided separately from the substrate transfer devices 13 and 17. For example, the reverser turns over the wafer W immediately before the wafer W is carried into the processing device 16 (brush processing device) and immediately after the wafer W is carried out from the processing device 16 (brush processing device).

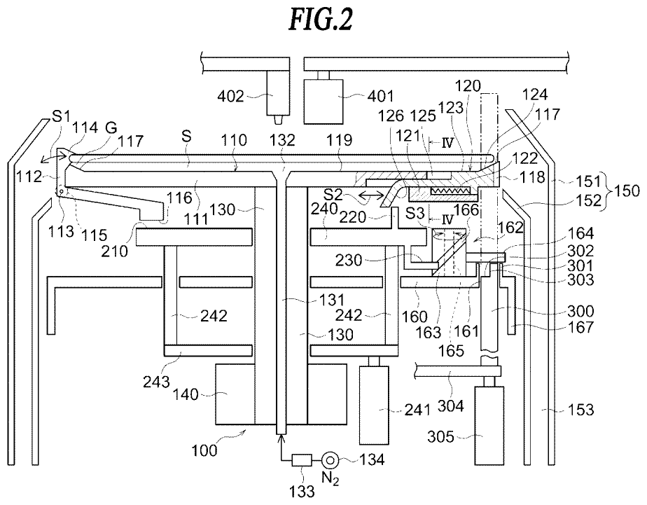

Now, a configuration of the processing device 16 will be explained with reference to FIG. 2 to FIG. 4. As depicted in FIG. 2, the processing device 16 is equipped with a spin chuck (substrate holding/rotating mechanism) 100 configured to hold the wafer W (substrate) horizontally and rotate it around a vertical axis. The spin chuck 100 includes a substrate holder 110, a rotation shaft 130, and a rotational driver 140. The rotational driver 140 is configured by, for example, an electric motor.

The substrate holder 110 includes a disk-shaped plate 111; and a plurality of, e.g., three (only one is shown in FIG. 1) chuck members 112 (substrate gripping members) provided to a periphery of the plate 111. The three chuck members 112 are positioned so as to equally divide the periphery of the plate 111 into three parts in a circumferential direction.

Each chuck member 112 of the substrate holder 110 is configured to be rotated around a rotation shaft 113, which is provided at the periphery of the plate 111, between a gripping position (a position shown in FIG. 2) where the wafer W is gripped and a releasing position where the wafer is released (see arrow S1 in FIG. 2).

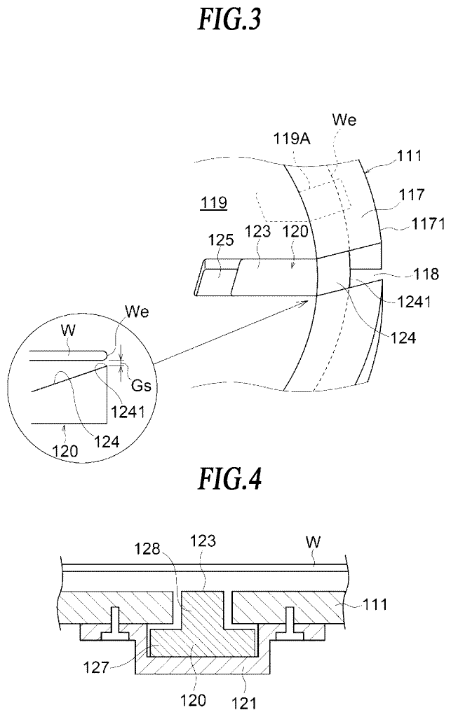

As shown in FIG. 2 and FIG. 3, the plate 111 is provided with, on a periphery of a top surface thereof, an inclined surface 117 which becomes higher as it approaches the periphery of the plate 111. In the present exemplary embodiment, a region of the top surface of the plate 111 radially inside the inclined surface 117 is a horizontal surface 119. When the wafer W is transferred between the spin chuck 100 and a substrate holding arm of an internal transfer device (in the present exemplary embodiment, the substrate transfer device 17 shown in FIG. 1), the wafer W is temporarily placed on the inclined surface 117.

By rotating the chuck member 112 from the releasing position to the gripping position in the state that the wafer W is placed on the inclined surface 117 of the plate 111, a gripping claw 114 of the chuck member 112 is engaged with an APEX (outer peripheral edge) of the wafer W, and lifts up the wafer W from the inclined surface 117 to grip it. At this time, a small gap G (for example, a gap of about 0.5 mm when measured in a vertical direction) is formed between the inclined surface 117 and a periphery of a bottom surface of the wafer W.

By rotating the chuck member 112 holding the wafer W from the gripping position to the releasing position, the gripping claw 114 of the chuck member 112 is distanced away from the wafer W, and the wafer W falls onto the inclined surface 117 to be supported by the inclined surface 117.

The chuck member 112 is biased toward the gripping position by a spring 115 (for example, a torsion coil spring) which is schematically indicated by a dashed line in FIG. 2. Therefore, after the wafer W is gripped by the gripping claw 114 of the chuck member 112, the wafer W is kept held by the chuck member 112 even if no external force (other than that from the spring 115) is applied to the chuck member 112.

The chuck member 112 has pushing target member 116 on the opposite side of the gripping claw 114 with respect to the rotation shaft 113. By pushing the pushing target member 116 upwards with a chuck operating member 210, the chuck member 112 can be rotated to the releasing position where the gripping claw 114 is away from the wafer W.

Further, in order to enable the chuck member 112 to grip the wafer W placed on the inclined surface 117, a notch is provided at the inclined surface 117 in a minimum amount to fit the shape of the chuck member 112. As compared to a notch 118 to be described later, this notch has almost no adverse effect on a flow of an inert gas to be described later.

A gas supply path 131 is extended inside the rotation shaft 130 of the spin chuck 100. An upper end of the gas supply path 131 is formed as a gas discharge hole 132 through which an inert gas (for example, a nitrogen gas) is discharged toward a space S between the bottom surface of the wafer W held by the substrate holder 110 and the top surface of the plate 111. The gas discharge hole 132 may be formed so that a vector indicating a mainstream direction of the gas discharged therefrom has a component directed toward the periphery of the plate 111, or may be configured to discharge the gas vertically upwards.

A lower end of the gas supply path 131 is connected to an inert gas source 134 via a gas supply control mechanism 133. The gas supply control mechanism 133 is equipped with devices such as an opening/closing valve, a flow control valve, and a flow meter, and is capable of performing a switchover between discharging of the gas from the gas discharge hole 132 and stopping of the discharging of the gas, and also capable of controlling a gas discharge rate. The inert gas source 134 is, for example, a factory power supply provided in a semiconductor manufacturing factory.

When the wafer W is being processed while being held and rotated by the spin chuck 100, the inert gas is supplied from the gas discharge hole 132. The inert gas flows through the space S between the wafer W and the plate 111 toward the periphery of the wafer W, and then flows out from the space S through the gap G between the periphery of the wafer W and the periphery of the plate 111.

The gas supply path 131, the gas discharge hole 132, the gas supply control mechanism 133, and so forth constitute a gas supply device together.

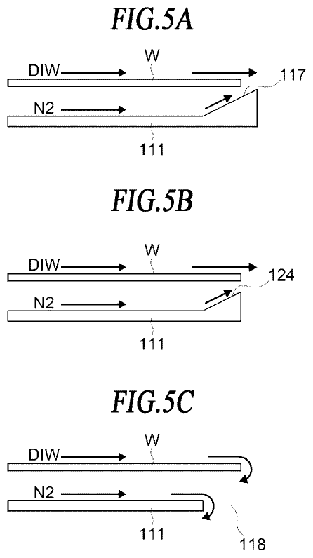

As illustrated in FIG. 5A, when the inert gas approaches the gap G, the flow of the inert gas is diverted toward the periphery of the bottom surface of the wafer W by the inclined surface 117. Thus, even if a liquid such as DIW (pure water) supplied to the top surface of the wafer W attempts to flow to the bottom surface of the wafer W, such attempt is suppressed by the flow of the inert gas. In addition, due to the presence of the inclined surface 117, a distance of the space S in a height direction becomes smaller (that is, an area of a flow path of the inert gas decreases) as approaching the gap G. Thus, as the inert gas approaches the gap G, the flow rate of the inert gas increases, whereby the aforementioned effect of suppressing the flow of the liquid to the bottom surface is promoted.

The processing device 16 is equipped with a plurality of, here, three lift pins 300. The lift pins 300 serve to relay the transferring of the wafer W between the arm of the external transfer device (in the present embodiment, the arm of the substrate transfer device 17 shown in FIG. 1) and the spin chuck 100. The three lift pins 300 are arranged at approximately mid-positions between the adjacent chuck members 112 in the circumferential direction of the plate 111, when viewed from the top.

A head 301 of each lift pin 300 (substrate elevating member) has a shape suitable for holding the periphery of the wafer W. In the present exemplary embodiment, the head 301 has a supporting surface 302 facing upwards for supporting the periphery of the bottom surface of the wafer W; and a position regulating surface 303 facing inwards in the radial direction of the wafer W for regulating the position of the APEX of the wafer W in the radial direction. The supporting surface 302 supports, for example, a region corresponding to an edge exclusion of the surface (here, the surface facing downwards) of the wafer W on which devices are to be formed.

Lower ends of the three lift pins 300 are mounted to, for example, a ring-shaped elevating body 304. The elevating body 304 is configured to be moved up and down by an elevating mechanism configured by a linear actuator 305 such as an air cylinder. Along with this elevating operation, the lift pins 300 can be moved in a vertical direction between a raised position (a wafer delivery position indicated by a dashed line in FIG. 2) and a lowered position (a standby position indicated by a solid line in FIG. 2).

In addition, as can be seen from the raised position of the lift pin 300 shown in FIG. 2, the actual length of the lift pin 300 is longer than that shown by the solid line. Further, although the elevating body 304 and the linear actuator 305 are actually located below the illustrated positions, they are illustrated as being located at the shown positions for convenience of illustration.

Since the head 301 of the lift pin 300 is to be engaged with the periphery of the wafer W, the head 301 has to be configured to penetrate the periphery of the plate 111. To this end, the notch 118 is formed at the periphery of the plate 111 to allow the lift pin 300 to pass therethrough in the vertical direction. That is, the inclined surface 117 provided on the periphery of the top surface of the plate 111 is discontinuous at the point where the notch 118 is provided. The notch 118 is clearly marked in FIG. 3.

If this notch 118 is left as it is (that is, if a slider 120 to be described later is not provided), the inert gas flows downwards at the point where the notch 118 is provided, as shown in FIG. 5C. As a result, most of the flow of the inert gas along the periphery of the bottom surface of the wafer W may disappear. Resultantly, the flow of the liquid from the top surface of the wafer W to the bottom surface thereof cannot be suppressed. If the liquid that has reached the bottom surface is dried, particles are generated.

To solve the aforementioned problem, a slider (sliding member) 120 as a closing block capable of blocking at least a portion of the notch 118 located directly below the wafer W is provided at the plate 111. The slider 120 can be slid horizontally in the radial direction of the plate 111 between a closing position where it blocks the notch 118 at least partially and an opening position where it opens the notch 118 to allow the lift pin 300 to pass through the notch 118.

A top surface of the slider 120 has a horizontal surface 123 on the inner side (center side of the plate 111) and an inclined surface (end inclined surface) 124 on the outer side (peripheral side of the plate 111). The horizontal surface 123 is on a level with the horizontal surface 119 located more centrally than the inclined surface 117 of the plate 111.

As shown in FIG. 3, the inclined surface 124 is sloped so that its height increases as it goes toward the outer side (peripheral side of the plate 111). When the slider 120 is located at the closing position, the inclined surface 124 of the slider 120 is approximately level with the inclined surface (peripheral inclined surface) 117 of the plate 111. In other words, when viewed from the circumferential direction of the plate 111, the inclined surface 124 of the slider 120 is substantially continuous with the inclined surface 117 of the plate 111.

As schematically illustrated in FIG. 5B, the inclined surface 124 of the slider 120 located at the closing position is capable of diverting, like the inclined surface 117 of the plate 111 (see FIG. 5A), the inert gas flowing horizontally between the plate 111 and the wafer W toward the bottom surface of the wafer W. Therefore, the inert gas can be suppressed from flowing downwards at the notch 118, and, as a result, it is possible to suppress the liquid from reaching the bottom surface of the wafer W from the top surface thereof.

When the wafer W is gripped by the chuck member 112 of the spin chuck 100, a leading end 1241 (see FIG. 3) of the inclined surface 124 of the slider 120 placed at the closing position is located almost directly below an edge We of the wafer W. The position of the edge We is indicated by a dashed line in the perspective view of FIG. 3. Here, it is desirable that a distance GS (see FIG. 3) between the edge We of the wafer W and the leading end 1241 of the inclined surface 124 of the slider 120 measured in the vertical direction is set to a small value of, e.g., 0.5 mm or less.

Furthermore, the reason why the leading end edge (periphery) 1171 (see FIG. 3) of the inclined surface 117 of the plate 111 is positioned radially outer than the leading end 1241 of the inclined surface 124 of the slider 120 located at the closing position is because the inclined surface 117 is used to temporarily place the wafer W thereon. The leading end 1241 may be set to be coincident with the leading end edge 1171. In that case, however, the aforementioned distance GS need to be increased. Meanwhile, the leading end edge 1171 of the inclined surface 117 may be made to coincide with the edge We of the wafer W when viewed from the top. In that case, however, a device configured to directly transfer the wafer W to the chuck member 112 without placing it on the inclined surface 117 is required. Taking all of these into account, the layout shown in FIG. 3 is currently regarded as the best layout.

In consideration of the flow of inert gas near the periphery of the bottom surface of the wafer, it is desirable that the slider 120 has the inclined surface 124. However, an embodiment in which the entire top surface of the slider 120 is configured as a horizontal surface is also possible. As long as the slider 120 at the closing position blocks the notch 118 directly below the wafer W, the downflow of inert gas as shown in FIG. 5C decreases, so it is possible to suppress the liquid from flowing to the bottom surface of the wafer W from the top surface thereof. Further, this configuration in which the slider 120 does not have the inclined surface 124 also has an advantage in that there is no need to expose a slit 125 to be described later on the top surface 119 of the plate 111.

Now, a moving mechanism of the slider 120 will be explained. As illustrated in FIG. 2, the plate 111 of the substrate holder 110 is equipped with a guide member 121 configured to guide the slider 120 horizontally in the radial direction of the plate 111. The guide member 121 is immovable with respect to the plate 111. A configuration of this guide member 121 is not particularly limited as long as it allows the slider 120 to be slid horizontally and smoothly in the radial direction of the plate 111.

The slider 120 has a surface facing inwards in the radial direction of the plate 111, and the guide member 121 has a surface facing outwards in the radial direction of the plate 111. A spring (compression spring) is provided between these opposing surfaces. The slider 120 is biased toward the closing position by this spring 122. Accordingly, when no external force (other than the one from the spring 122) is applied to the slider 120, the slider 120 is positioned at the closing position.

The slider 120 is provided with an inclined surface 126 (an inclined surface along which a slider operating member 220 to be described later is operated) that is inclined with respect to a horizontal plane (directed obliquely downwards). The inclined surface 126 is inclined so as to become higher as it approaches an outer side of the slider 120 (as it approaches an outer peripheral edge of the plate 111). For example, by bringing a head of the slider operating member 220 in the form of a pin extending in a vertical direction into contact with the inclined surface 126 and moving (sliding) it upwards, the slider 120 guided by the guide member 121 is slid toward the opening position against the biasing force of the spring 122 (see arrow S2 in FIG. 2).

As shown in FIG. 2 and FIG. 3, the slit 125 is provided on the top surface of the plate 111 to enable the slider 120 to be moved between the closing position and the opening position. There is a risk that the inert gas escape to below the plate 111 from a portion of the slit 125 where the slider 120 is not present. Further, in order to enable a smooth operation of the slider 120, the width of the slit 125 is set to be slightly larger than the width of the slider 120. For this reason, there is also a risk that the inert gas may escape to below the plate 111 through a gap between a sidewall of the slit 125 and a sidewall of the slider 120. In order to make such a gas leak less likely to occur, the guide member 121 may be configured to surround the slider 120, as schematically shown in FIG. 4. Alternatively, the width of a lower portion 127 of the slider 120 positioned below the slit 125 may be made larger than the width of an upper portion 128 of the slider 120 within the slit 125. In addition, although the shape shown in FIG. 4 does not strictly match that shown in FIG. 2, it is here to be understood that FIG. 4 is only a schematic diagram.

Instead of the notch 118 in the form of the recess extending from the periphery of the plate 111 toward the center thereof, a notch (outlined by a dashed line 119A in FIG. 3) in the form of a hole may be provided at the periphery of the plate 111 to allow the lift pin 300 penetrating the periphery of the plate 111 in the vertical direction to pass therethrough. This notch in the form of the hole is not open on the periphery of the plate 111. It is apparent that this hole can also be opened and closed by the above-described slider.

Now, a structure provided around the spin chuck 100 will be described with reference to FIG. 2. A liquid receiving cup 150 is provided around the spin chuck 100 to receive and collect a liquid scattered from the wafer W held by the substrate holder 110. In the shown example, the liquid receiving cup 150 has an outer cup body 151 and an inner cup body 152, and the liquid flows down a passage 153 between the outer cup body 151 and the inner cup body 152. As is well known in the technical field of semiconductor manufacturing equipment, by further providing one or more movable cup bodies between the outer cup body 151 and the inner cup body 152, a plurality of passages may be formed between every two adjacent cup bodies, and the liquid may be drained through one of the passages selected according to the kind of the liquid supplied to the wafer W.

An upper end of the inner cup body 152, which is the innermost cup body, is disposed close to the plate 111, making it difficult for the liquid scattered from the wafer W to reach a space directly below the plate 111. The processing device 16 is equipped with various actuators (an air cylinders, a motor, etc.) and their accompanying electrical circuits. In order to reliably protect these actuators and electrical circuits from a contaminated atmosphere including mist of the processing liquid (the liquid supplied to wafer W) or the like, a partition member 160 is provided below the plate 111. The actuators, the electrical circuits, etc. are provided below this partition member 160.

The partition member 160 is formed in, for example, a disk shape as a whole, and a side circumferential member 167 that hangs downwards is provided at an outer peripheral edge of the disk shape along the entire circumference thereof. A hole is provided at a center of the partition member 160 to allow the rotation shaft 130 of the spin chuck 100 to pass therethrough.

The partition member 160 is also provided with three holes 161 through which the three lift pins 300 respectively pass. The partition member 160 is equipped with movable covers 162 each configured to block the hole 161 when the lift pin 300 is located at the lowered position. The movable cover 162 has a substantially cylindrical base 163 and a cover main body 164 extending radially outward from the base 163. The base 163 is rotatably mounted around a shaft 165 provided at the partition member 160.

A groove 166 is formed on an outer circumference surface of the base 163 so as to extend obliquely on the outer circumference surface. The groove 166 is formed so that h, which denotes a height position, increases with a rise of θ, which denotes an angular position on the outer circumference surface. A cover operating member 230 configured to rotate the movable cover 162 is engaged in this groove 166. By moving the cover operating member 230 up and down, the base 163 and the cover main body 164 are rotated around the shaft 165 (see arrow S3 in FIG. 2). Along this rotational operation, the cover main body 164 is moved between a closing position where it closes the hole 161 and an opening position where it opens the hole 161 to allow the lift pin 300 to pass through the hole 161. That is, the base 163 provided with the groove 166 and the cover operating member 230 constitute a cylindrical cam mechanism. Here, the hole 161 is opened when the cover operating member 230 is placed at a raised position, and the hole 161 is closed when the cover operating member 230 is placed at a lowered position. By closing the hole 161, it is possible to more reliably suppress the contaminated atmosphere from reaching a space below the partition member 160.

The three operating members (the chuck operating member 210, the slider operating member 220, and the cover operating member 230) described above are supported by a single elevating member 240. These operating members 210, 220 and 230 may be integrally molded with the elevating member 240, or may be provided separately from the elevating member 240 and then fixed to the elevating member 240. The chuck operating member 210 may be a top surface of the elevating member 240 itself, or may be a protrusion extending upwards from the top surface of the elevating member 240.

The elevating member 240 has, for example, a substantially disk shape as a whole. A hole is provided at a center of the elevating member 240 to allow the rotation shaft 130 of the spin chuck 100 to pass therethrough. Gaps are provided between the rotation shaft 130 of the spin chuck 100 and the holes at the centers of the elevating member 240 and the partition member 160, so the elevating member 240 and the partition member 160 are not rotated even when the rotation shaft 130 of the spin chuck 100 is rotated.

The elevating member 240 can be moved up and down by an elevation device composed of a linear actuator 241 such as an air cylinder. One or more rods 242 extending downwards from a bottom surface of the elevating member 240 are extended through the partition member 160. Lower ends of the rod 242 are connected to a single disk-shaped elevating body 243, and this elevating body 243 is raised and lowered by the linear actuator 241.

The linear actuator 241 is provided below the partition member 160. By moving the elevating member 240 up and down, the chuck operating member 210, the slider operating member 220, and the cover operating member 230 can be moved up and down concurrently.

When the elevating member 240 is moved up, the chuck operating member 210 raises the pushing target member 116 of the chuck member 112, and, accordingly, the chuck member 112 is moved to the releasing position. Further, the slider operating member 220 comes into contact with the inclined surface 126 of the slider 120 to push the inclined surface 126 upwards, and, accordingly, the slider 120 is moved to the opening position. In addition, the cover operating member 230 rotates the movable cover 162, so that the cover main body 164 is moved to the opening position. As a result, the lift pin 300 can be freely raised and lowered between the raised position and the lowered position.

When the elevating member 240 is moved down, the chuck operating member 210 is moved away from the pushing target member 116 of the chuck member 112, and, accordingly, the chuck member 112 is moved to the gripping position. Further, the slider operating member 220 is moved away from the inclined surface 126 of the slider 120, and, accordingly, the slider 120 is moved to the closing position. Furthermore, the cover operating member 230 rotates the movable cover 162, so that the cover main body 164 is moved to the closing position.

Now, a processing performed on a single sheet of wafer W in the processing device 16 will be explained.

The arm of the substrate transfer device 17 holding an unprocessed wafer W is carried into the processing device 16 to stand by at a delivery position (a position directly above the spin chuck 100). Further, the elevating member 240 is raised, allowing the lift pins 300 to be freely moved up and down between the raised position and the lowered position. Then, the lift pins 300 are raised to receive the wafer W from the arm of the substrate transfer device 17. Subsequently, the arm of the substrate transport device 17 is retreated from the processing device 16.

Next, the lift pins 300 supporting the wafer W thereon are lowered to the lowered position. When the wafer W is placed on the inclined surface 117 while the lift pins 300 are being lowered, the wafer W is moved away from the lift pins 300. Then, by moving the elevating member 240 to the lowered position, the chuck member 112 is moved to the gripping position to grip the wafer W, and, accordingly, the wafer W is moved slightly apart from the inclined surface 117. Further, the slider 120 and the cover main body 164 are moved to the closing position. Accordingly, the wafer W is ready to be processed.

Here, it is assumed that the processing performed on the wafer W is the brush processing performed on the rear surface (the surface on which the device is to be formed) of the wafer W. In this case, since the wafer W is turned over by the reverser before being carried into the processing device 16, the wafer W is held on the spin chuck 100 with the rear surface thereof facing upwards. While rotating the wafer W by the spin chuck 100, a brush cleaning process, a two-fluid cleaning process, a rinsing process, and a drying process, for example, are performed in sequence.

In the brush cleaning process, the two-fluid cleaning process, and the rinsing process, the processes are performed in the state that a liquid (for example, DIW) is supplied on the rear surface (the surface facing upwards (top surface)) of the wafer W. In the brush cleaning process, a brush 401 being rotated is moved between a central portion and a peripheral portion of the wafer W while being pressed against the top surface of the wafer W being rotated. At this time, a liquid (for example, DIW) is supplied to the wafer W from a liquid discharge structure embedded in the brush 401. In the two-fluid cleaning process, a nozzle 402 configured to discharge a two-fluid containing a cleaning liquid (for example, DIW) and a gas (for example, a nitrogen gas) toward the top surface of the wafer W being rotated is reciprocated between a position above the central portion of the wafer W and a position above the peripheral portion of the wafer W. In the rinsing process, a rinse liquid (for example, DIW) is supplied from the nozzle 402 (or another nozzle) to the central portion of the top surface of the wafer W being rotated.

In order to suppress the liquid supplied to the top surface of the wafer W from reaching the bottom surface (the surface on which the device is to be formed) of the wafer W to contaminate the bottom surface of the wafer W, the inert gas is supplied into the space S between the top surface of the plate 111 and the bottom surface of the wafer W from the gas discharge hole 132. As previously explained with reference to FIG. 5A to FIG. 5C, this effect of suppressing the flow of the liquid to the bottom surface of the wafer W by the inert gas is exerted over the entire circumference of the wafer W due to the slider 120 placed at the closing position.

The drying process is performed by rotating the wafer W at a high speed without supplying a liquid to the top surface of the wafer W. Upon the completion of the drying process, the series of processes of the processing on the single sheet of wafer W are ended.

Upon the completion of the processing of the wafer W, the elevating member 240 is moved to the raised position. Along with this, the chuck member 112 is moved to the releasing position, and the wafer W having been gripped by the chuck member 112 is dropped onto the inclined surface 117 of the plate 111. Furthermore, the slider 120 and the cover main body 164 are moved to the opening position. Subsequently, the lift pins 300 are raised, and the wafer W is lifted from the inclined surface 117 by the lift pins 300. The lift pins 300 supporting the wafer W thereon are then raised up to the raised position. Next, the empty arm of the substrate transfer device 17 is positioned at the delivery position within the processing device 16, and by lowering the lift pins 300 in this state, the wafer W is handed over to the substrate transfer device 17. Subsequently, the arm of the substrate transfer device 17 holding the wafer W thereon is taken out from the processing device 16.

According to the above-described exemplary embodiment, since the slider 120 at least partially blocks the notch 118 of the plate 111 when the wafer W is being processed, the contamination of the bottom surface of the wafer W due to the flow of the liquid to the bottom surface of the wafer W can be suppressed near the notch 118.

Further, by moving the slider operating member 220 upwards, the slider 120 is moved to the opening position against the elastic force of the spring 122, and by moving the slider operating member 220 downwards, the slider 120 is moved to the closing position to be fixed thereat by the elastic force of the spring 122. For this reason, when the spin chuck 100 is being rotated, there is no need to apply an external force (other than the spring force) to the slider 120 to fix the slider 120 at the closing position.

In addition, by moving the chuck operating member 210 upwards, the chuck member 112 is moved to the releasing position against the elastic force of the spring 115, and by moving the chuck operating member 210 downwards, the chuck member 112 is moved to the gripping position by the elastic force of the spring 115. For this reason, when the spin chuck 100 is being rotated, there is no need to apply an external force (other than the spring force) to the chuck member 112 to fix the chuck member 112 at the gripping position.

The slider 120 and the chuck member 112 are placed at positions suitable for mounting and unmounting the wafer W to/from the spin chuck 100 by locating their operating members 220 and 210 at the raised positions. In addition, the slider 120 and the chuck member 112 are placed at positions suitable for processing the wafer W while rotating it on the spin chuck 10 by locating their operating members 220 and 210 at the lowered positions. For this reason, by integrating the slider operating member 220 and the chuck operating member 210 with the single elevating member 240, the slider 120 and the chuck member 112 can be moved simultaneously toward the required positions by a single elevational driving mechanism (here, the linear actuator 241). Therefore, the number of components of the processing device 16 can be reduced, so that the manufacturing cost of the processing device 16 can be reduced.

Moreover, the cover main body 164 is moved to the opening position by moving the cover operating member 230 to the raised position, and is moved to the closing position by moving the cover operating member 230 to the lowered position. That is, like the slider 120 and the chuck member 112, the cover main body 164 is also placed at a position suitable for mounting and unmounting the wafer W to/from the spin chuck 100 by locating its operating member (cover operating member 230) at the raised position, and is placed at a position suitable for processing the wafer W while rotating it on the spin chuck 100 by locating its operating member (cover operating member 230) at the lowered position. Therefore, by integrating the cover operating member 230 with the single elevating member 240, the slider 120, the chuck member 112, and the cover main body 164 can be moved to the required positions simultaneously by the single elevational driving mechanism (here, the linear actuator 241). For this reason, the number of the components of the processing device 16 can be reduced, so that the manufacturing cost of the processing device 16 can be reduced.

In the above-described exemplary embodiment, the chuck operating member 210, the slider operating member 220, and the cover operating member 230 are all integrated with the single elevating member 240 and are moved up and down along with the elevating member 240. Although this configuration is most desirable from the viewpoint of reducing the number of the components of the processing device 16 and cutting the manufacturing cost, the present disclosure is not limited thereto. That is, in a modification of the exemplary embodiment, two of the chuck operating member 210, the slider operating member 220 and the cover operating member 230 may be integrated with the elevating member 240, while the remaining one is not integrated with the elevating member 240 but is operated by another driving source. By way of example, there may be considered a modification of the exemplary embodiment in which the slider operating member 220 and the cover operating member 230, which are closely related to the raising and the lowering of the lift pins 300, are integrated with the elevating member 240, whereas the chuck operating member 210 is not integrated with the elevating member 240 but is driven by another driving source. In this case as well, the number of the components of the processing device 16 can be reduced, so that the manufacturing cost of the processing device 16 can be cut.

Although the processing device 16 according to the above-described exemplary embodiment is suitable for processing the rear surface of the wafer W in the state that the rear surface of the wafer W faces upwards, the processing device 16 can also process the front surface of the wafer W with the front surface of the wafer W facing upwards. In addition, the processing performed in this processing device 16 is not limited to the brush processing described above, and may be a chemical processing (a chemical cleaning processing, an etching processing, etc.). No matter what kind of processing is performed, the effect of suppressing the flow of the liquid from the top surface to the bottom surface of the wafer W by the slider 120 can be obtained.

It should be noted that the above-described exemplary embodiment is illustrative in all aspects and is not anyway limiting. The above-described exemplary embodiment may be omitted, replaced and modified in various ways without departing from the scope and the spirit of claims.

The substrate as the processing target is not limited to the semiconductor wafer, and may be any of various types of substrates for use in the field of semiconductor device manufacturing, such as a glass substrate and a ceramic substrate.

According to the exemplary embodiment, it is possible to efficiently suppress the particle generation that may be caused by providing the notch in the plate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a substrate holder, configured to hold a substrate horizontally, including a plate positioned below the substrate when the substrate holder is holding the substrate; and multiple substrate gripping members provided on a periphery of the plate and configured to hold the substrate, the plate having multiple notches at the periphery thereof;
a rotational driver configured to rotate the substrate holder around a vertical axis;
multiple lift pins configured to support a periphery of the substrate from below, and configured to be moved up and down through the notches of the plate;
multiple sliding members provided on the plate of the substrate holder and configured to be slid in a horizontal direction, each of the multiple sliding members being configured to be moved between a closing position where the corresponding notch of the plate is at least partially closed and an opening position where the corresponding notch of the plate is opened to allow the corresponding lift pin to be moved up and down through the corresponding notch; and
multiple operating members provided below the plate of the substrate holder to be moved up and down and allowed to be respectively engaged with the sliding members, each of the multiple operating members being configured to slide the corresponding sliding member in the horizontal direction by being moved up and down while being engaged with the corresponding sliding member.

2. The substrate processing apparatus of claim 1,
wherein each of the sliding members is provided to the plate via a guide structure configured to guide the sliding member in the horizontal direction, and has an operating target inclined surface inclined with respect to a horizontal plane, and
the sliding member is moved in the horizontal direction by moving the operating member up and down while sliding the operating member along the operating target inclined surface in a state that the operating member is in contact with the operating target inclined surface.

3. The substrate processing apparatus of claim 1,
wherein the sliding member is spring-biased toward the closing position.

4. The substrate processing apparatus of claim 1, further comprising:
an elevating body provided below the plate to support the multiple operating members for the sliding members; and
an elevational driver configured to move the elevating body up and down between a raised position and a lowered position,
wherein as the elevating body is moved up and down, the multiple operating members for the sliding members are also moved up and down.

5. The substrate processing apparatus of claim 4,
a partition member configured to separate at least a space in which an actuator configured to move the lift pins up and down and the rotational driver provided below the elevating body are disposed from a space in which the elevating body is disposed.

6. The substrate processing apparatus of claim 5,
wherein the partition member is provided with through holes through which the lift pins are allowed to pass therethrough; and cover members each configured to be moved between a closing position where the corresponding through hole is closed and an opening position where the corresponding through hole is opened, and
wherein when located at the lowered position, the lift pin is positioned below the cover member located at the closing position, and when the lift pin is raised from the lowered position, the cover member is opened.

7. The substrate processing apparatus of claim 6,
wherein the cover member is moved between the closing position where the through hole is closed and the opening position where the through hole is opened by being operated with an operating member for the cover member supported by the elevating body.

8. The substrate processing apparatus of claim 7,
wherein the cover member includes a cylindrical base having a groove formed on an outer circumferential surface thereof and configured to be rotated about a rotation shaft extending in a vertical direction; and a cover main body provided to the base,
the operating member for the cover member is engaged in the groove of the cylindrical base,
the groove of the base and the operating member for the cover member constitute a cylindrical cam mechanism, and
by moving the elevating body toward the lowered position, the base is rotated and the cover main body closes the through hole, and by moving the elevating body toward the raised position, the base is rotated and the cover main body opens the through hole.

9. The substrate processing apparatus of claim 8,
wherein the substrate gripping member of the substrate holder is rotatably provided to the periphery of the plate, and is configured to be moved between a gripping position where the substrate is gripped and a releasing position where the substrate is released,
the substrate gripping member includes a gripper configured to grip the periphery of the substrate, and an operating target member configured to move the gripper;
the elevating body comprises an operating member for the operating target member configured to push up the operating target member of the substrate gripping member, and the operating member for the operating target member is configured as a member supported by the elevating body or the elevating body itself, and
by locating the elevating body at the lowered position, the substrate gripping member is placed at the gripping position, and by locating the elevating body at the raised position, the substrate gripping member is placed at the releasing position.

10. The substrate processing apparatus of claim 1, further comprising:
a gas supply configured to supply a gas into a space between a bottom surface of the substrate held by the substrate holder and a top surface of the plate of the substrate holder,
wherein the gas supplied into the space flows through the space between the top surface of the plate and the bottom surface of the substrate, and then flows out from the space through a gap between the periphery of the plate and the periphery of the substrate.

11. The substrate processing apparatus of claim 10,
wherein a periphery of the top surface of the plate has a peripheral inclined surface that becomes higher as approaching the periphery of the plate, and the peripheral inclined surface of the plate diverts the gas flowing horizontally after passing through the space towards the bottom surface of the substrate,
an end inclined surface is provided at an end portion of the top surface of each sliding member, and the end inclined surface is formed so as to be continuous with the peripheral inclined surface of the plate when the sliding member is placed at the closing position, when viewed from a circumferential direction of the plate.

12. The substrate processing apparatus of claim 2,
wherein the sliding member is spring-biased toward the closing position.

13. The substrate processing apparatus of claim 2, further comprising:
a gas supply configured to supply a gas into a space between a bottom surface of the substrate held by the substrate holder and a top surface of the plate of the substrate holder,
wherein the gas supplied into the space flows through the space between the top surface of the plate and the bottom surface of the substrate, and then flows out from the space through a gap between the periphery of the plate and the periphery of the substrate.

14. The substrate processing apparatus of claim 13,
wherein a periphery of the top surface of the plate has a peripheral inclined surface that becomes higher as approaching the periphery of the plate, and the peripheral inclined surface of the plate diverts the gas flowing horizontally after passing through the space towards the bottom surface of the substrate,
an end inclined surface is provided at an end portion of the top surface of each sliding member, and the end inclined surface is formed so as to be continuous with the peripheral inclined surface of the plate when the sliding member is placed at the closing position, when viewed from a circumferential direction of the plate.

15. The substrate processing apparatus of claim 3, further comprising:
a gas supply configured to supply a gas into a space between a bottom surface of the substrate held by the substrate holder and a top surface of the plate of the substrate holder,
wherein the gas supplied into the space flows through the space between the top surface of the plate and the bottom surface of the substrate, and then flows out from the space through a gap between the periphery of the plate and the periphery of the substrate.

16. The substrate processing apparatus of claim 15,
wherein a periphery of the top surface of the plate has a peripheral inclined surface that becomes higher as approaching the periphery of the plate, and the peripheral inclined surface of the plate diverts the gas flowing horizontally after passing through the space towards the bottom surface of the substrate,
an end inclined surface is provided at an end portion of the top surface of each sliding member, and the end inclined surface is formed so as to be continuous with the peripheral inclined surface of the plate when the sliding member is placed at the closing position, when viewed from a circumferential direction of the plate.

17. The substrate processing apparatus of claim 4, further comprising:
a gas supply configured to supply a gas into a space between a bottom surface of the substrate held by the substrate holder and a top surface of the plate of the substrate holder,
wherein the gas supplied into the space flows through the space between the top surface of the plate and the bottom surface of the substrate, and then flows out from the space through a gap between the periphery of the plate and the periphery of the substrate.

18. The substrate processing apparatus of claim 17,
wherein a periphery of the top surface of the plate has a peripheral inclined surface that becomes higher as approaching the periphery of the plate, and the peripheral inclined surface of the plate diverts the gas flowing horizontally after passing through the space towards the bottom surface of the substrate,
an end inclined surface is provided at an end portion of the top surface of each sliding member, and the end inclined surface is formed so as to be continuous with the peripheral inclined surface of the plate when the sliding member is placed at the closing position, when viewed from a circumferential direction of the plate.

19. The substrate processing apparatus of claim 5, further comprising:
a gas supply configured to supply a gas into a space between a bottom surface of the substrate held by the substrate holder and a top surface of the plate of the substrate holder,
wherein the gas supplied into the space flows through the space between the top surface of the plate and the bottom surface of the substrate, and then flows out from the space through a gap between the periphery of the plate and the periphery of the substrate.

20. The substrate processing apparatus of claim 19,
wherein a periphery of the top surface of the plate has a peripheral inclined surface that becomes higher as approaching the periphery of the plate, and the peripheral inclined surface of the plate diverts the gas flowing horizontally after passing through the space towards the bottom surface of the substrate,
an end inclined surface is provided at an end portion of the top surface of each sliding member, and the end inclined surface is formed so as to be continuous with the peripheral inclined surface of the plate when the sliding member is placed at the closing position, when viewed from a circumferential direction of the plate.
